(19) United States
(12) Patent Application Publication
(10) Pub. No.: US 2022/0178976 A1
(43) Pub. Date: Jun. 9, 2022

(54) FREQUENCY ESTIMATION AND TRACKING USING CURRENT

(71) Applicant: Schweitzer Engineering Laboratories, Inc., Pullman, WA (US)

(72) Inventors: Kei Hao, Anaheim, CA (US); Daqing Hou, Des Moines, WA (US)

(73) Assignee: Schweitzer Engineering Laboratories, Inc., Pullman, WA (US)

(21) Appl. No.: 17/113,725

(22) Filed: Dec. 7, 2020

(51) Int. Cl. G01R 19/25; G01R 21/133; G01R 19/175

(52) U.S. Cl. CPC G01R 19/2509; G01R 19/175; G01R 19/2513; G01R 21/133

(57) ABSTRACT

The present disclosure relates to systems and methods tracking an alternating current frequency in an electric power system. In one embodiment, a system may include a waveform receiving subsystem to receive a representation of a current waveform. A sampling subsystem may sample the representation of a current waveform at a first estimated frequency and generate a sampled representation of the current waveform. A filtered and sampled representation of the current waveform may be generated using a filter subsystem. A period subsystem may determine an estimated period of the filtered and sampled representation of the current waveform. A frequency determination subsystem may determine a second estimated frequency based on the estimated period. The second estimated frequency may then be used by the sampling subsystem in a subsequent iteration to sample a subsequent representation of the current waveform.

### TECHNICAL FIELD

The present disclosure pertains to estimating and tracking a frequency of an alternating current in an electric power system. More particularly, but not exclusively, the present disclosure pertains to line-mounted current sensors that estimate and track the frequency of an alternating current to generate a sampled representation of the alternating current that may be used to monitor, automate, and/or protect the electric power system.

### BRIEF DESCRIPTION OF THE DRAWINGS

Non-limiting and non-exhaustive embodiments of the disclosure are described, including various embodiments of the disclosure with reference to the figures, in which:

FIG. 1 illustrates a simplified one-line diagram of an electric power delivery system consistent with embodiments of the present disclosure.

FIG. 2A illustrates a plot of a current measured by a line-mounted current sensor over time and showing significant distortion consistent with embodiments of the present disclosure.

FIG. 2B illustrates a portion of the plot in FIG. 2A overlayed with an output of a cosine filter consistent with embodiments of the present disclosure.

FIG. 3 illustrates a data flow for tracking a frequency of a current waveform consistent with embodiments of the present disclosure.

FIG. 4 illustrates a data flow for frequency discrimination consistent with embodiments of the present disclosure.

FIG. 5A illustrates a plot over time of sampled data and a current waveform consistent with embodiments of the present disclosure.

FIG. 5B illustrates an enlarged portion of the graph of FIG. 5A and illustrates use of linear interpolation consistent with embodiments of the present disclosure.

FIG. 6 illustrates a flow chart of a method for estimating and tracking a frequency of an electric power system using a current sensor consistent with embodiments of the present disclosure.

FIG. 7 illustrates a functional block diagram of a system to track a frequency of an alternating current in an electric power system consistent with embodiments of the present disclosure.

### DETAILED DESCRIPTION

Electric power systems are used to generate, transmit, and distribute electric power to loads, and serve as an important part of critical infrastructure. Electric power systems and equipment may be monitored and protected by a variety of types of equipment. Protection relays may analyze the parameters of an electric power system to implement protective functions. The primary protective relays may communicate with various other supervisory devices such as automation systems, monitoring systems, supervisory (SCADA) systems, and other intelligent electronic devices (IEDs). IEDs may collect data from various devices within an electric power system and monitor, control, automate, and/or protect such devices.

Protective relays typically use voltage measurements to estimate system frequency and track frequency changes because voltages usually exhibit less waveform distortions (e.g., harmonic distortions) than currents; however, voltage measurements may not be available to some types of equipment (e.g., line sensors) or in some applications. When voltage signals are unavailable, the distortions in current signals may make frequency estimation and tracking more challenging.

The inventors of the present disclosure have recognized that the systems and methods disclosed herein may allow for improved tracking of an electric system by tracking system frequency using current measurements. In various embodiments, line sensors consistent with the present disclosure analyze zero crossing of a current signal to estimate periods and track the period changes. The estimated periods and period changes may be used to determine a data sampling period so that a specified number of samples per cycle can be obtained by a current sensor. The sampled data can then be used to compute a variety of quantities and for a wide range of applications such as fault current magnitude, fault direction, and high impedance fault detection, etc. The sampled data may be provided to a variety of equipment used to automate, monitor, and protect the power system, such as protective relays, IEDs, control systems, etc.

As used herein, an IED may refer to any microprocessor-based device that monitors, controls, automates, and/or protects monitored equipment within a system. Such devices may include, for example, differential relays, distance relays, directional relays, feeder relays, overcurrent relays, voltage regulator controls, voltage relays, breaker failure relays, generator relays, motor relays, remote terminal units, automation controllers, bay controllers, meters, recloser controls, communications processors, computing platforms, programmable logic controllers (PLCs), programmable automation controllers, input and output modules, and the like. The term IED may be used to describe an individual IED or a system comprising multiple IEDs. Further, IEDs may include sensors (e.g., voltage transformers, current transformers, contact sensors, status sensors, light sensors, tension sensors, etc.) that provide information about the electric power system.

The embodiments of the disclosure will be best understood by reference to the drawings. It will be readily understood that the components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments of the disclosure. In addition, the steps of a method do not necessarily need to be executed in any specific order, or even sequentially, nor do the steps need to be executed only once, unless otherwise specified.

In some cases, well-known features, structures, or operations are not shown or described in detail. Furthermore, the described features, structures, or operations may be combined in any suitable manner in one or more embodiments. It will also be readily understood that the components of the embodiments, as generally described and illustrated in the figures herein, could be arranged and designed in a wide variety of different configurations. For example, throughout this specification, any reference to “one embodiment,” “an embodiment,” or “the embodiment” means that a particular feature, structure, or characteristic described in connection with that embodiment is included in at least one embodiment. Thus, the quoted phrases, or variations thereof, as recited throughout this specification are not necessarily all referring to the same embodiment.

Several aspects of the embodiments disclosed herein may be implemented as software modules or components. As used herein, a software module or component may include any type of computer instruction or computer-executable code located within a memory device that is operable in conjunction with appropriate hardware to implement the programmed instructions. A software module or component may, for instance, comprise one or more physical or logical blocks of computer instructions, which may be organized as a routine, program, object, component, data structure, etc., that performs one or more tasks or implements particular abstract data types.

In certain embodiments, a particular software module or component may comprise disparate instructions stored in different locations of a memory device, which together implement the described functionality of the module. A module or component may comprise a single instruction or many instructions and may be distributed over several different code segments, among different programs, and across several memory devices. Some embodiments may be practiced in a distributed computing environment where tasks are performed by a remote processing device linked through a communications network. In a distributed computing environment, software modules or components may be located in local and/or remote memory storage devices. In addition, data being tied or rendered together in a database record may be resident in the same memory device, or across several memory devices, and may be linked together in fields of a record in a database across a network.

Embodiments may be provided as a computer program product including a non-transitory machine-readable medium having stored thereon instructions that may be used to program a computer or other electronic device to perform processes described herein. The non-transitory machine-readable medium may include, but is not limited to, hard drives, floppy diskettes, optical disks, CD-ROMs, DVD-ROMs, ROMs, RAMs, EPROMs, EEPROMs, magnetic or optical cards, solid-state memory devices, or other types of media/machine-readable media suitable for storing electronic instructions. In some embodiments, the computer or another electronic device may include a processing device such as a microprocessor, microcontroller, logic circuitry, or the like. The processing device may further include one or more special-purpose processing devices such as an application-specific interface circuit (ASIC), PAL, PLA, PLD, field-programmable gate array (FPGA), or any other customizable or programmable device.

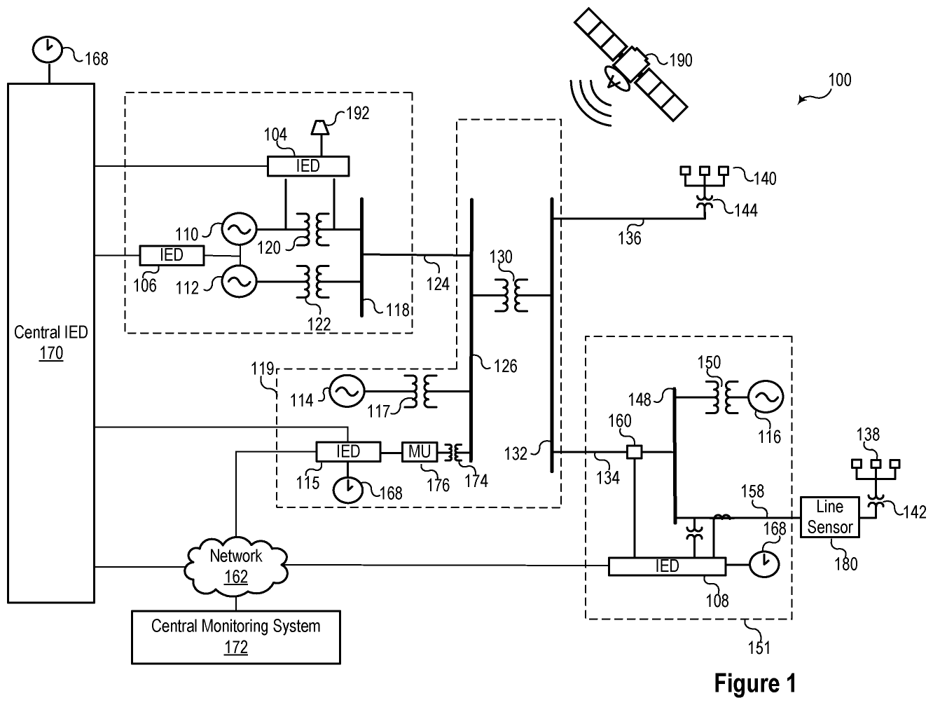

FIG. 1 illustrates a simplified one-line diagram of an electric power delivery system 100 consistent with embodiments of the present disclosure. Electric power delivery system 100 may be configured to generate, transmit, and distribute electric energy to loads. Electric power delivery systems may include equipment such as electrical generators (e.g., generators 110, 112, 114, and 116), transformers (e.g., transformers 117, 120, 122, 130, 142, 144, 150, and 174), power transmission and delivery lines (e.g., lines 124, 134, 136, and 158), circuit breakers (e.g., breaker 160), busses (e.g., busses 118, 126, 132, and 148), loads (e.g., loads 140 and 138) and the like. A variety of other types of equipment may also be included in electric power delivery system 100, such as voltage regulators, capacitor banks, and the like.

Substation 119 may include a generator 114, which may be a distributed generator, and which may be connected to bus 126 through step-up transformer 117. Bus 126 may be connected to a distribution bus 132 via a step-down transformer 130. Various distribution lines 136 and 134 may be connected to distribution bus 132. Load 140 may be fed from distribution line 136. Further, step-down transformer 144 in communication with distribution bus 132 via distribution line 136 may be used to step down a voltage for consumption by load 140.

Distribution line 134 may lead to substation 151 and deliver electric power to bus 148. Bus 148 may also receive electric power from distributed generator 116 via transformer 150. Distribution line 158 may deliver electric power from bus 148 to load 138 and may include further step-down transformer 142. Circuit breaker 160 may be used to selectively connect bus 148 to distribution line 134. IED 108 may be used to monitor and/or control circuit breaker 160 as well as distribution line 158.

Electric power delivery system 100 may be monitored, controlled, automated, and/or protected using IEDs, such as IEDs 104, 106, 108, 115, and 170, and a central monitoring system 172. In general, IEDs in an electric power generation and transmission system may be used for protection, control, automation, and/or monitoring of equipment in the system. For example, IEDs may be used to monitor equipment of many types, including electric transmission lines, electric distribution lines, current transformers, busses, switches, circuit breakers, reclosers, transformers, autotransformers, tap changers, voltage regulators, capacitor banks, generators, motors, pumps, compressors, valves, and a variety of other types of monitored equipment.

Central monitoring system 172 may comprise one or more of a variety of types of systems. For example, central monitoring system 172 may include a supervisory control and data acquisition (SCADA) system and/or a wide area control and situational awareness (WACSA) system. A central IED 170 may be in communication with IEDs 104, 106, 108, and 115. IEDs 104, 106, 108, and 115 may be remote from the central IED 170 and may communicate over various media such as a direct communication from IED 106 or over a wide-area communications network 162. According to various embodiments, certain IEDs may be in direct communication with other IEDs (e.g., IED 104 is in direct communication with central IED 170) or may be in communication via a communication network 162 (e.g., IED 108 is in communication with central IED 170 via communication network 162).

A common time signal 168 may be used to time-align measurements for comparison and/or synchronize action across system 100. Utilizing a common or universal time source may allow for the generation of time-synchronized data, such as synchrophasors. In various embodiments, the common time source may comprise a time signal from a GNSS system 190. IED 104 may include a receiver 192 configured to receive the time signal 168 from the GNSS system 190. In various embodiments, IED 106 may be configured to distribute the time signal 168 to other components in system 100, such as IEDs 104, 108, 115, and 170.

A voltage transformer 174 may be in communication with a merging unit (MU) 176. MU 176 may provide information from voltage transformer 174 to IED 115 in a format useable by IED 115. MU 176 may be placed near to voltage transformer 174 and may digitize discrete input/output (I/O) signals and analog data, such as voltage measurements. These data may then be streamed to IED 115. In various embodiments, MU 176 may be located outside of a substation enclosure or control house, thus increasing safety by removing high-energy cables from areas where personnel typically work. In various embodiments, MU 176 may be embodied as an SEL-2240 available from Schweitzer Engineering Laboratories of Pullman, Wash.

A variety of sensors, such as line sensor 180, may be distributed throughout system 100 to provide information regarding electrical conditions used for automation, monitoring, and protection. Line sensor 180 may track the frequency of alternating current through transmission line 158 to determine a data sampling period and obtain a specified number of samples per cycle. The sampled data may be provided to IED 108 or another device for use in a variety of applications, such as determining a fault current magnitude, determining a fault direction, and detecting a high impedance fault, etc.

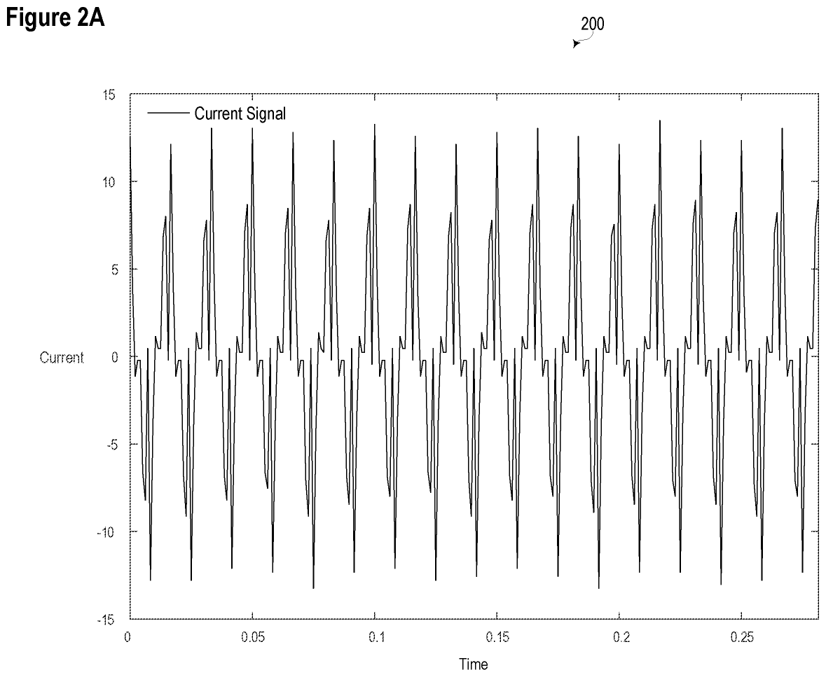

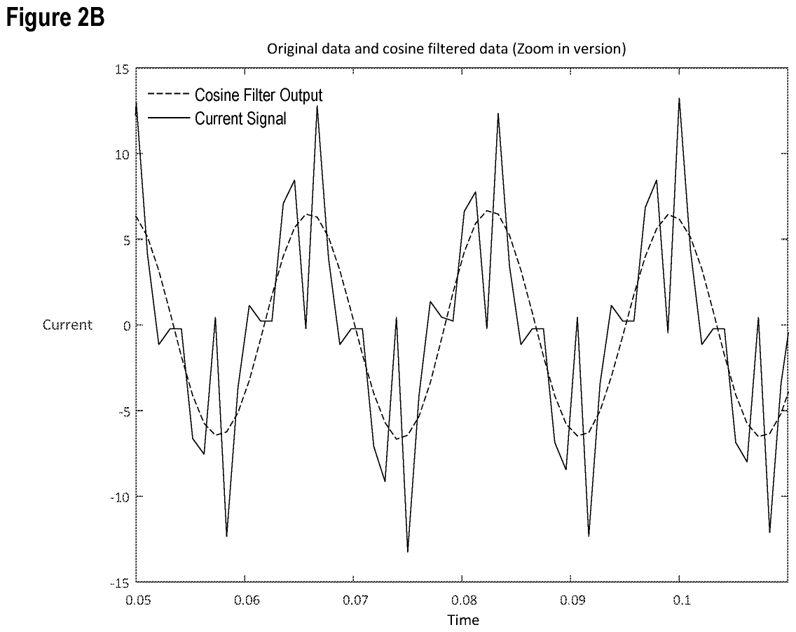

FIG. 2A illustrates a plot of a current measured by a line-mounted current sensor over time and showing significant distortion. As indicated above, voltage measurements are not typically available in line sensors and the current may exhibit more distortions. The plot illustrated in FIG. 2A shows heavy harmonic and non-linear load distortions. The distortions include spurious zero crossings that would interfere with traditional systems and methods that use zero crossings to estimate the frequency of the signal. Such distortions may make frequency estimation and tracking more challenging for line sensors, and accordingly, various embodiments consistent with the present disclosure may utilize a variety of techniques to accurately determine and track a frequency of an electric power system.

FIG. 2B illustrates a portion of the plot in FIG. 2A overlayed with an output of a cosine filter. The cosine filter smooths out the significant distortions of the current signal. Further, the cosine filter output eliminates the spurious zero crossings in the original signal. Various embodiments consistent with the present disclosure may use cosine filters, in combination with other techniques, to accurately determine and track a frequency of an electric power system using a current measurement.

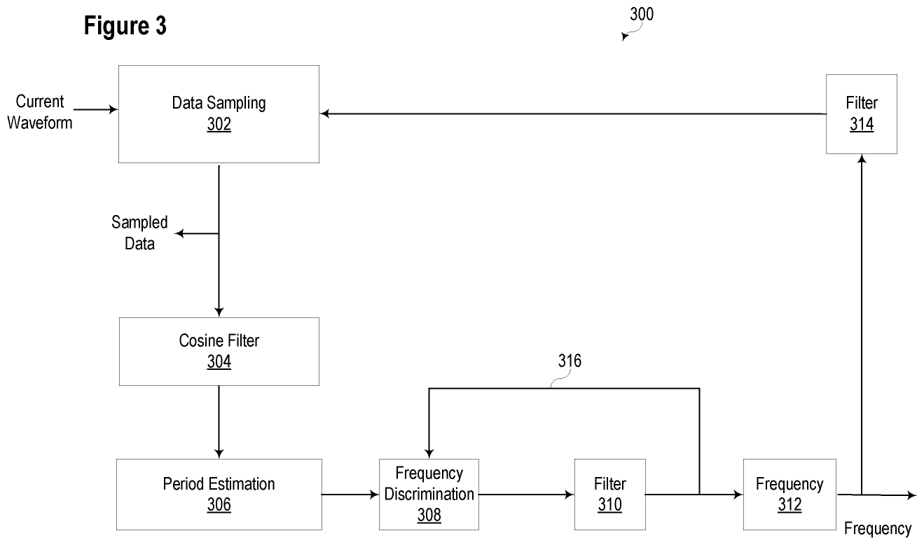

FIG. 3 illustrates a data flow 300 for tracking a frequency of a current waveform consistent with embodiments of the present disclosure. A current waveform may be provided as an input. Sampled data from the current waveform and a frequency may be provided as an output. Devices that may be used for current sensing may include, but are not limited to, shunt resistors, current transformers, Rogowski coils, hall effect sensors, flux gate sensors, magneto-resistive current sensors, etc. The sampled data output may be used for a variety of applications, including determination of a fault magnitude, determination of a fault direction, high impedance fault detection, etc.

A data sampling 302 block may obtain a specified number of samples per cycle (e.g., 8, 16, 32, 64 samples per cycle). Data sampling 302 block may be initialized with an estimated frequency equal to an electric power system's fundamental frequency (e.g., 50 Hz, 60 Hz), and may then use the techniques discussed below to determine the actual frequency of the system. In some embodiments, the data sampling frequency remains constant within a cycle and changes from cycle to cycle.

The current waveform input may be passed to a cosine filter 304 block. Cosine filter 304 block may remove distortions (e.g., DC components, harmonic distortions, etc.) of the alternating current signal without affecting the fundamental frequency of the signal. The elimination of such distortions may reduce or eliminate spurious zero crossings that may be used in generating an estimate of the frequency. Various numbers of taps may be used by cosine filter 304 block (e.g., 8, 16, 32, or 64 taps). Although a cosine filter is illustrated in FIG. 3, other types of filters (e.g., a FIR or IIR filter designed to remove a fundamental frequency and harmonic components) may be utilized in other embodiments.

A period estimation 306 block may generate an estimate of the period of the current based on the sampled and filtered data. In various embodiments, period estimation 306 block may estimate the period using zero crossings of the signal and linear interpolation. Period estimation 306 block may use either rising or falling zero crossings. One advantage of using zero crossings is that the system does not require a high-precision time source to accurately determine the frequency using the techniques disclosed herein.

A frequency discrimination 308 block may selectively discard sudden changes in frequency. In various embodiments, frequency discrimination 308 block may compare a change in the frequency to a threshold. If the change is less than the threshold, the estimated period may be used in a subsequent iteration, but if the change exceeds the threshold, frequency discrimination 308 block may discard the estimated period and instead use a prior frequency value as illustrated by arrow 316.

A filter 310 block may smooth the output of the period according to specific response criteria. Frequency in an electric power system changes smoothly due to a variety of factors (e.g., spinning inertia associated with various types of generation). Filter 310 block may ensure that the changes reflect constraints on frequency changes in physical systems. In some embodiments, filter 310 block is implemented using an infinite impulse response filter or a finite impulse response filter. In other embodiments, filter 310 block is implemented using an Olympic Filter, which rejects the largest and smallest measurements and averages the remaining measurements.

A frequency 312 block may convert the period of the current waveform to a frequency measurement using the reciprocal relationship between period and frequency. The frequency may be an output used by other systems to monitor, automate, and/or protect an electric power system.

The frequency may also be used in a feedback loop by in data flow 300. In the illustrated embodiment, the frequency is filtered by filter 314 block before being fed back into data sampling 302 block. Filter 314 block may smooth adjustments of the sampling rate used by data sampling 302 block. In some embodiments, the filtering performed by cosine filter 304 block, filter 310 block, and filter 314 block may be accomplished using a filter subsystem or filter module.

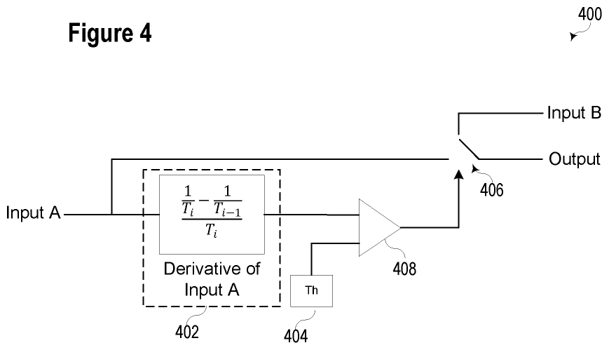

FIG. 4 illustrates a data flow 400 for frequency discrimination consistent with embodiments of the present disclosure. In the illustrated embodiment, two frequency inputs, Input A and Input B, are provided. A derivative of Input A may be determined by block 402. The derivative may be compared to a threshold 404 by a comparator 408 If the derivative (i.e., the rate of change) of the frequency on Input A is less than the threshold 404, the output of the comparator 404 may connect Input A to an Output. If the derivative exceeds the threshold 404, the output may be connected to Input B, thus discarding Input A. In one embodiment, the data flow 400 may be embodied as frequency discrimination 308 block in FIG. 3.

Frequency discrimination may increase the accuracy of frequency tracking by eliminating distortions. Distortions may be severe as a result of saturation. Saturation may occur as a result of a fault that causes a sudden change in current. In such a scenario, a frequency determined just prior to the fault may be used. Various parameters associated with a fault, such as magnitude estimation, may be estimated based on a frequency determined before the fault.

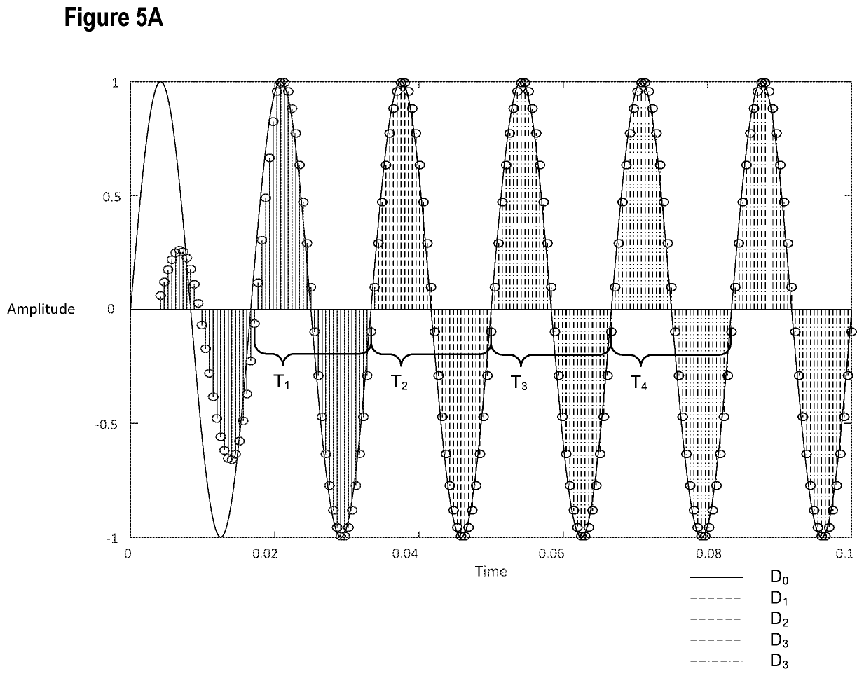

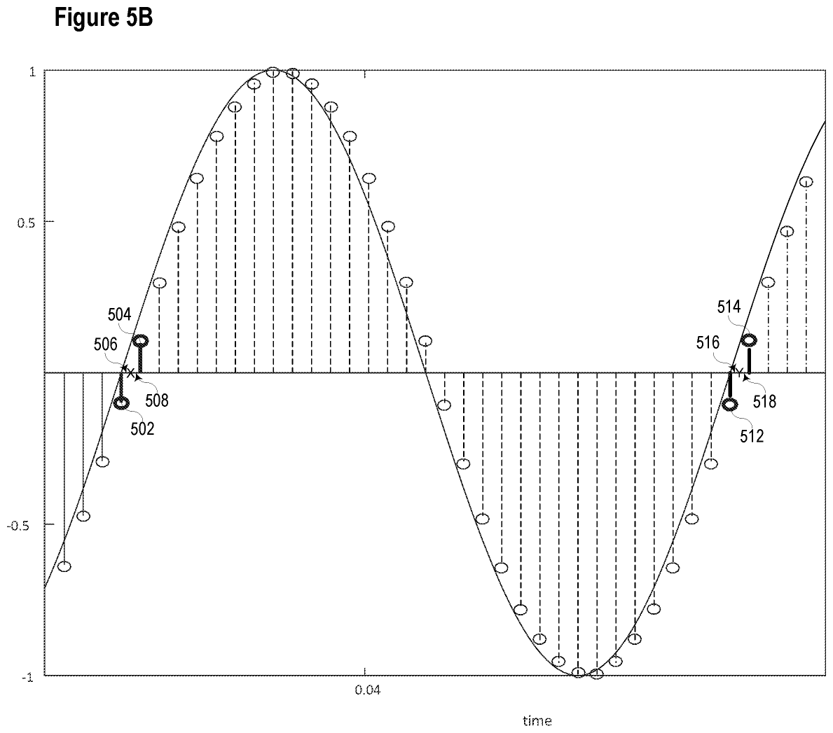

FIG. 5A illustrates a plot over time of sampled data and a current waveform consistent with embodiments of the present disclosure. The solid line may correspond to the current waveform, while the sampled values are each designated by a line at the sampling time and a dot corresponding to the sampled value. In the illustrated embodiment, the current waveform is sampled 32 times per complete cycle, and the samples in each cycle are identified using a different line pattern. A delay in the sampled values when the system starts may result from filtering in the system; however, after approximately one cycle, the sampled values approximate both the frequency and amplitude of the current waveform. During an initial period, a fundamental frequency of an electric system may be used (e.g., 60 Hz).

A sampling interval, Dₙ, may be established and used for each cycle. Each sampling interval is identified in FIG. 5A using a different line pattern. In various embodiments, the sampling interval and frequency estimate may be adjusted every cycle. The sampling interval may be determined using the estimated frequency during the period, fₙ, and a number of samples per cycle, N, using Eq. 1.

$${D}_{n} = \frac{1 / {f}_{n}}{N} \qquad Eq . 1$$

For example, where the estimated frequency is 60, and the number of samples per cycle is 32, the sampling interval is 5.203̅×10⁻⁴ seconds. In various embodiments, a system consistent with the present disclosure may set an interrupt at the sampling interval (e.g., 5.203̅×10⁻⁴ seconds) and may enter a power-saving mode between measurements to reduce power consumption. The sampling interval may be adjusted each period, and an appropriate schedule of interrupts may be set to wake the system from a power-saving mode in time for each measurement.

For each period, a time interval, Tₙ, may be determined between a first rising zero crossing and a subsequent rising zero crossing. The time intervals for the four cycles (i.e., T₁, T₂, T₃, and T₄) are shown in FIG. 5A. In some embodiments, the time interval may be equal to the product of the sampling interval and the number of samples per period (i.e., Tₙ=Dₙ*N). The frequency for each period, fₙ, may be determined using the reciprocal relationship between the time interval and the frequency (i.e., fₙ=1/Tₙ).

FIG. 5B illustrates an enlarged portion of the graph of FIG. 5A and illustrates use of linear interpolation consistent with embodiments of the present disclosure. Two points 502, 504 associated with a first zero crossing may be identified, with point 502 being below zero and point 504 being above zero. Points 502, 504 are identified with thickened lines for ease of reference. A time interval 506 between point 502 and the zero crossing, which is designated with an “X,” may be determined, along with a time interval 508 between the zero crossing and point 504. Time interval 508 may be designated D₀₋t₂, where D₀ is the sampling rate in the prior period.

Additional points 512, 514 associated with a second zero crossing may also be identified, with point 512 being below zero and point 514 being above zero. A time interval 516 between point 516 and the zero crossing, which is designated with a “Y” may be determined, along with a time interval 518 between the zero crossing and point 514. Time interval 518 may be designated where D₁ is the sampling rate in the current period.

The time intervals determined using interpolation may be used to estimate the period in some embodiments. In such embodiments, the period may be calculated using Eq. 2, where N is the number of samples per period.

Period=(N−1)*D₁+D₀₋t₂+D₁₋t₁ Eq. 2

The period determined using Eq. 2 may yield a better estimate than simply relying on the product of the sampling interval and the number of samples per period (i.e., Tₙ=Dₙ*N), as discussed above. The period determined using Eq. 2 may also be used to determine a frequency using the reciprocal relationship between period and frequency.

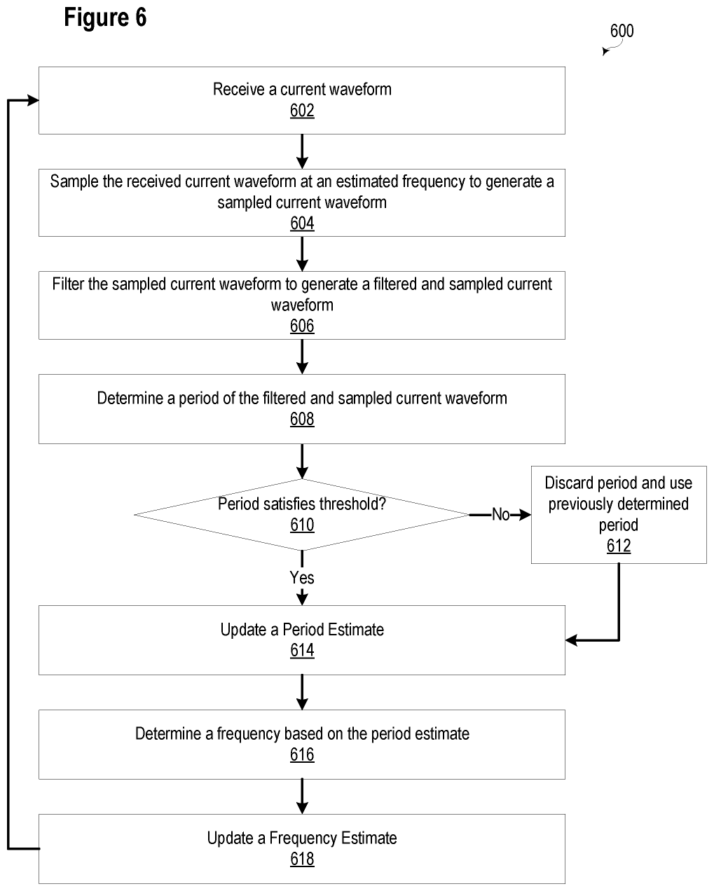

FIG. 6 illustrates a flow chart of a method 600 for estimating and tracking a frequency of an electric power system using a current sensor consistent with embodiments of the present disclosure. At 602, a system may receive a current waveform. In some embodiments, the current waveform is directly detected by a device implementing method 600 using a current sensor (e.g., a current transformer, a Rogowski coil, a hall effect sensor, a flux gate sensor, a magneto-resistive current sensor, etc.). In other embodiments, the current waveform may be communicated to a device through various communication protocols.

At 604, the current waveform may be sampled at an estimated frequency to generate a sampled current waveform. During an initial period, the estimated frequency may equal the nominal frequency of an electric power system (e.g., 60 Hz, 50 Hz). After an initial period, the estimated frequency may be updated at a specified interval (e.g., once per half-cycle, once per cycle, once every two cycles, etc.). The sampled current waveform may be used for various functions, such as determining a fault current magnitude, a determining fault direction, and detecting a high impedance fault, etc.

At 606, the sampled current waveform may be filtered to generate a filtered and sampled current waveform. The filter may smooth out distortions of the current signal and eliminate the spurious zero crossings. Various embodiments consistent with the present disclosure may use cosine filters or other techniques to achieve similar results.

At 608, a period of the filtered and sampled current waveform may be determined. In various embodiments, the period is determined using zero crossings of the waveform, as illustrated and described in connection with FIG. 5A and FIG. 5B.

At 610, it may be determined whether the period determined at 608 satisfies a threshold. If the change is less than the threshold, the estimated period may be used in a subsequent iteration. If the change exceeds the threshold, the period may be discarded and a previously determined period may be used at 612.

At 614, a period estimate may be up updated, using either the period determined at 608 or using a previously determined period. In some embodiments, the period estimate may be used to set a schedule for transitioning between a power-saving mode and an active mode to save power. In such embodiments, an interrupt may be set based on the sampling interval to ensure that a system implementing method 600 is active at the time a measurement is to be made. The sampling interval may be periodically adjusted, and an appropriate schedule of interrupts may be set to wake the system from a power-saving mode in time for each measurement.

At 616, a frequency may be determined based on the period estimate. The frequency may be determined using the reciprocal relationship between period and frequency. In some embodiments, filtering may also be performed to smooth fluctuations in frequency. Such smoothing may reflect physical constraints of electric power systems that resist rapid changes in frequency.

At 618, a frequency estimate may be updated and method 600 may repeat using the updated frequency estimate. Method 600 may repeat at various intervals (e.g., twice per cycle, once per cycle, once every two cycles, etc.).

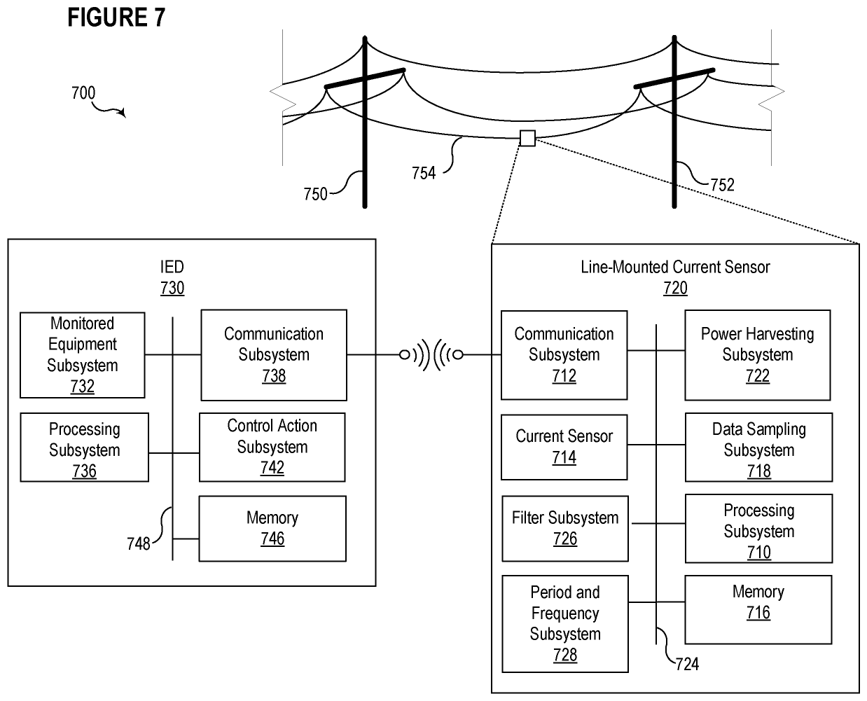

FIG. 7 illustrates a functional block diagram of a system 700 to track a frequency of an alternating current in an electric power system consistent with embodiments of the present disclosure. System 700 may be implemented using hardware, software, firmware, and/or any combination thereof. The specifically illustrated configuration is merely representative of one embodiment consistent with the present disclosure.

Line-mounted current sensor 720 is mounted to conductor 754, which is suspended between pylons 750, 752. Only a single line-mounted wireless current sensor 720 is illustrated. In other embodiments, multiple line-mounted current sensors may be used, or IED 730 may assume that the current on other phases are the same magnitude as the first current but shifted in phase (i.e., shifted by 120 degrees in a three-phase system).

Line-mounted current sensor 720 and IED 730 each contain various subsystems represented by functional blocks. The functional blocks in line-mounted current sensor 720 may communicate using data bus 724, and the functional blocks in IED 730 may communicate using data bus 748.

A communication subsystem 712 may be configured to communicate information, such as sampled current measurements obtained by line-mounted current sensor 720, to IED 730. Wireless communication subsystem 712 may utilize various technologies to enable wireless communication. Such communication may include radio frequency communications and may employ analog or digital modulation techniques and protocols. Wireless communication subsystem 712 may enable transmission of data from line-mounted current sensor 720 related to electrical parameters associated with conductor 754. In some embodiments, communication subsystem 712 may enable bi-directional communication between line-mounted current sensor 720 and IED 730, while in other embodiments, communication may be unidirectional.

A current sensor 714 may obtain a current waveform representing current flowing through conductor 754. Current sensor 714 may be embodied as a current transformer, a Rogowski coil, a hall effect sensor, a flux gate sensor, a magneto-resistive current sensor, or other current-sensing device. The measurements obtained by current sensor 714 may be subject to substantial distortion, including the types of distortions illustrated in FIG. 2A and discussed above. Other functional units may condition the current waveform such that line-mounted current sensor 720 can accurately track the frequency of the alternating current flowing in conductor 754. Although FIG. 7 utilizes a current sensor 714 to generate a representation of the alternating current waveform in conductor 754, in other embodiments, the representation of the waveform may be received by a waveform receiving subsystem. Such a waveform receiving subsystem may include a current sensor, such as current sensor 714, and may also include other elements that may be used to receive a representation of a waveform (e.g., communication subsystem 712, a network interface, a monitored equipment interface, etc.).

A power harvesting subsystem 722 may harvest power from conductor 754. In some embodiments, power harvesting subsystem 722 may utilize a current transformer to harvest energy from conductor 754. In various embodiments, the current transformer used to harvest power from conductor 754 may also provide a signal that is analyzed and used to obtain electrical parameter measurements from conductor 754. Power harvesting subsystem 722 may further incorporate a power storage device that may be used to transmit information when current is not flowing through conductor 754 and power cannot be harvested. A power storage device may be embodied as a battery, a supercapacitor, and the like. Line-mounted current sensor 720 may reduce the need for ongoing maintenance associated with devices powered with batteries.

A data sampling subsystem 718 may be configured to obtain data samples from a current waveform representing current flowing through conductor 754. Data sampling subsystem 718 may obtain a specified number of samples per cycle (e.g., 8, 16, 32, 64 samples per cycle). Data sampling subsystem 718 may be initialized with an estimated frequency equal to an electric power system's fundamental frequency (e.g., 50 Hz, 60 Hz.), and may then use the techniques discussed below to determine the actual frequency of the system. In some embodiments, the data sampling frequency remains constant within a cycle and changes from cycle to cycle. In other embodiments, the sampling frequency may be changed with more frequency (e.g., every half cycle) or less frequency (e.g., every two cycles).

A period and frequency subsystem 728 may generate an estimate of an alternating current period and frequency. In various embodiments, period and frequency subsystem 728 may estimate the period using zero crossings of the current signal. In some embodiments, the time of the zero crossings may be estimated using linear interpolation. Period and frequency subsystem 728 may determine a frequency using a period based on the reciprocal relationship between period and frequency. Period and frequency subsystem 728 may also implement frequency discrimination, which is illustrated as block 308 in FIG. 3, to selectively discard sudden changes in frequency. In various embodiments, period and frequency subsystem 728 may compare a change in the frequency to a threshold. If the change is less than the threshold, the estimated period may be used in a subsequent iteration, but if the change exceeds the threshold, the estimated period may be discarded and a prior frequency value may be used.

A filter subsystem 726 may filter the current waveform generated by current sensor 714 and/or the estimates of period and frequency generated by the period and frequency subsystem 728. Filter subsystem 726 may implement various types of filters (e.g., cosine filters, Olympic filters, FIR filters, IIR filters, etc.). In various embodiments, filter subsystem 726 may implement cosine filter 304, filter 310, and filter 314 illustrated in FIG. 3.

A memory 716 may include computer system readable media in the form of volatile memory, such as random access memory (RAM) and/or cache memory. The memory 716 may further include other removable/non-removable, volatile/non-volatile computer system storage media. In various embodiments, the memory 716 may include at least one program product having a set of program modules that are configured to carry out the functions described herein.

A processing subsystem 710 may be configured to process information received from the data sampling subsystem 718, the wireless communication subsystem 712, and the memory 716. Processing subsystem 710 may operate using any number of processing rates and architectures. Processing subsystem 710 may be configured to perform various algorithms and calculations described herein. Processing subsystem 710 may be embodied as a general-purpose integrated circuit, an application-specific integrated circuit, a field-programmable gate array, and/or any other suitable programmable logic device.

Turning now to the functional blocks associated with IED 730, a monitored equipment subsystem 732 may be in communication with monitored equipment that is operable to control an aspect or a portion of an electric power system. The monitored equipment subsystem 732 may be configured to issue commands to and/or receive status information from monitored equipment. In certain embodiments, monitored equipment subsystem 732 may be in communication with, for example, a circuit breaker and may issue commands to the circuit breaker to selectively connect or disconnect portions of the electric power system.

Memory 746 may include computer system readable media in the form of volatile memory, such as random access memory (RAM) and/or cache memory. The memory 746 may further include other removable/non-removable, volatile/non-volatile computer system storage media. In various embodiments, the memory 746 may include at least one program product having a set of program modules.

Processing subsystem 736 may be configured to perform various algorithms and calculations described herein. In various embodiments, processing subsystem 736 may be embodied as a general-purpose integrated circuit, an application-specific integrated circuit, a field-programmable gate array, and/or any other suitable programmable logic device.

Wireless communication subsystem 738 may receive information from and/or send information to line-mounted current sensor 720. Wireless communication subsystem 738 may be compatible with the wireless communication subsystem 712, utilizing the same communication technology and communication protocol(s). In various embodiments, IED 730 may also comprise other communication interfaces (e.g., a wired communication interface) to communicate with other devices, such as other IEDs, a SCADA system, etc.

A control action subsystem 742 may implement control actions based on information received from line-mounted current sensor 720 and other electrical parameters associated with an AC signal on conductor 754. In some embodiments, control action subsystem 742 may control a circuit breaker, which may be selectively activated and deactivated based on electrical conditions. Control action subsystem 742 may issue commands to selectively connect and disconnect portions of an electric power system using monitored equipment subsystem 732.

While specific embodiments and applications of the disclosure have been illustrated and described, it is to be understood that the disclosure is not limited to the precise configurations and components disclosed herein. Accordingly, many changes may be made to the details of the above-described embodiments without departing from the underlying principles of this disclosure. The scope of the present invention should, therefore, be determined only by the following claims.

1. A system to track an alternating current frequency in an electric power system, comprising:
a waveform receiving subsystem to receive a representation of a current waveform;
a sampling subsystem to sample the representation of a current waveform at a first estimated frequency and to generate a sampled representation of the current waveform;
a filter subsystem to filter the sampled representation of the current waveform and to generate a filtered and sampled representation of the current waveform;
a period subsystem to determine an estimated period of the filtered and sampled representation of the current waveform; and
a frequency determination subsystem to determine a second estimated frequency based on the estimated period;
a power subsystem to harvest power from an electrical conductor to which a line-mounted sensor is electrically coupled;
wherein the second estimated frequency is used by the sampling subsystem in a subsequent iteration to sample a subsequent representation of the current waveform.

2. (canceled)

3. (canceled)

4. The system of claim 1, wherein the filter subsystem applies a cosine filter to sample the representation of the current waveform and to generate the filtered and sampled representation of the current waveform.

5. The system of claim 1, wherein the filter subsystem applies one of a finite impulse response filter, an infinite impulse response filter, and an Olympic filter to generate a smoothed output of the frequency determination subsystem, and wherein the second frequency is based on the smoothed output of the frequency determination subsystem.

6. The system of claim 1, wherein the system is configured to generate a schedule to enter a power-saving mode based on the first estimated frequency.

7. The system of claim 1, further comprising a communication subsystem to communicate the sampled representation of the current waveform to a protective device in the electric power system.

8. The system of claim 1, wherein the period subsystem is further configured to compare the period of the filtered and sampled representation of the current waveform to a threshold and to selectively discard the period when the period exceeds a threshold.

9. The system of claim 8, wherein the period subsystem is further configured to utilize a prior value of the period in the subsequent iteration when the period exceeds the threshold.

10. The system of claim 1, wherein the period subsystem is further configured to utilize interpolation to interpolate a zero-crossing value of the alternating current between a first value below zero and a second value above zero.

11. A method of tracking a frequency of an alternating current in an electric power system using a line-mounted sensor, comprising:
receiving, using a waveform receiving subsystem, a representation of the current waveform;
sampling, using a sampling subsystem, the representation of the current waveform at a first estimated frequency and generating a sampled representation of the current waveform;
filtering, using a filter subsystem, the sampled representation of the current waveform and generating a filtered and sampled representation of the current waveform;
determining, using a period subsystem, a period of the filtered and sampled representation of the current waveform;
determining, using a frequency determination subsystem, a second estimated frequency based on the period; and
harvesting, using a power subsystem, power from an electrical conductor to which the line-mounted sensor is electrically coupled;
wherein the sampling subsystem further uses the second estimated frequency in a subsequent iteration to sample a subsequent representation of the current waveform.

12. The method of claim 11, further comprising applying, using the filter subsystem, a cosine filter to sample the representation of the current waveform and to generate the filtered and sampled representation of the current waveform.

13. The method of claim 11, further comprising applying, using the filter subsystem, one of a finite impulse response filter, an infinite impulse response filter, and an Olympic filter to generate a smoothed output of the frequency determination subsystem and the second estimated frequency based on the smoothed output of the frequency determination subsystem.

14. The method of claim 11, further comprising generating a schedule to enter a power-saving mode based on the first estimated frequency.

15. The method of claim 11, further comprising communicating, using a communication subsystem, the sampled representation of the current waveform to a protective device in the electric power system.

16. The method of claim 11, further comprising comparing, using the period and frequency subsystem, the period of the filtered and sampled representation of the current waveform to a threshold and selectively discarding the period when the period exceeds a threshold.

17. The method of claim 16, further comprising the period and frequency subsystem utilizing a prior value of the period in the subsequent iteration when the period exceeds the threshold.

18. The method of claim 11, further comprising interpolating, using the period subsystem, a zero-crossing value of the alternating current between a first value below zero and a second value above zero.

19. A system comprising:
an intelligent electronic device (IED), comprising:
a first communication subsystem to receive a sampled representation of the current waveform from a line-mounted current sensor;
a control action subsystem to generate a control action based on the sampled representation of the current waveform;
the line-mounted current sensor comprising:
a waveform receiving subsystem to receive a representation of the current waveform;
a data sampling subsystem to sample the representation of the current waveform at a first estimated frequency and to generate the sampled representation of the current waveform;
a filter subsystem to filter the sampled representation of the current waveform and to generate a filtered and sampled representation of the current waveform;
a period subsystem to determine an estimated period of the filtered and sampled representation of the current waveform;
a frequency determination subsystem to determine a second estimated frequency based on the estimated period; and
a communication subsystem to transmit the sampled representation of the current waveform to the IED;
wherein the second estimated frequency is used by the data sampling subsystem in a subsequent iteration to sample a subsequent representation of the current waveform.

20. The system of claim 19, wherein the line-mounted current sensor is configured generate a schedule to enter a power-saving mode based on the first estimated frequency.
